(19) United States
(12) Patent Application Publication
(10) Pub. No.: US 2024/0061345 A1
(43) Pub. Date: Feb. 22, 2024

(54) METHODS AND SYSTEMS OF DETECTING DEFECTS OF WAFER

(71) Applicant: SAMSUNG ELECTRONICS CO., LTD., Suwon-si (KR)

(72) Inventors: Kibum LEE, Suwon-si (KR); Taesoo SHIN, Suwon-si (KR); Seulgi OK, Suwon-si (KR); Sungwook HWANG, Suwon-si (KR)

(73) Assignee: SAMSUNG ELECTRONICS CO., LTD., Suwon-si (KR)

(21) Appl. No.: 18/207,510

(22) Filed: Jun. 8, 2023

(30) Foreign Application Priority Data
Aug. 16, 2022 (KR) 10-2022-0102233
Nov. 14, 2022 (KR) 10-2022-0151986

(51) Int. Cl. G03F 7/20

(52) U.S. Cl. CPC G03F 7/7065

(57) ABSTRACT

A method of detecting defects of a wafer including generating a composite wafer map comprising defect points by combining a plurality of wafer level maps generated by measuring the wafer according to the respective process operations; sorting the defect points according to defect clusters using positions of the defect points included in the composite wafer map; and detecting an initial process operation, from among the respective process operations, in which a defect occurred, using operation information, for each of the defect clusters.

### CROSS-REFERENCE TO RELATED APPLICATIONS

This application is based on and claims priority under 35 U.S.C. §119 to Korean Patent Application No. 10-2022-0102233, filed on Aug. 16, 2022, and Korean Patent Application No. 10-2022-0151986, filed on Nov. 14, 2022, in the Korean Intellectual Property Office, the disclosures of which are incorporated by reference herein in their entireties.

### BACKGROUND

The present disclosure relates to defects of a wafer, and more particularly, to a method and a system of detecting an initial defect of a semiconductor wafer according to data regarding defects occurring on a bottom surface of the semiconductor wafer.

A bottom surface of a semiconductor wafer may be contaminated due to particles caused by friction and vibrations occurring during various processes. For example, due to a force and pressure applied between the wafer and the chuck during a photo process, a surface of a portion of the wafer may rise, and thus hot spots may be generated. When a size of hot spots exceeds a range of a depth of focus (DOF), a pattern of a product is not properly formed in a photo process, and as a result, defocus problems may occur. The defocus problems may degrade the productivity and quality of a semiconductor product and decrease in yield.

### SUMMARY

Example embodiments provide a method and a system for detecting defects on a bottom surface of a wafer at an early stage and for quickly searching for a process in which the defects are caused.

According to an aspect of an example embodiment, a method of detecting defects of a wafer, includes: generating a composite wafer map including defect points by combining a plurality of wafer maps generated by measuring the wafer according to respective process operations; sorting the defect points according to defect clusters based on positions of the defect points included in the composite wafer map; and detecting an initial process operation, from among the respective process operations, in which a defect occurred, based on operation information, for each of the defect clusters.

According to an aspect of an example embodiment, an apparatus for detecting defects of a wafer, includes: a memory storing a program and a processor configured to execute the program stored in the memory to: generate a composite wafer map including defect points by combining a plurality of wafer level maps generated by measuring the wafer according to respective process operations; sort the defect points according to defect clusters based on positions of the defect points included in the composite wafer map; and detect an initial process operation, from among the respective process operations, in which a defect occurred, based on operation information, for each of the defect clusters.

According to an aspect of an example embodiment, a non-transitory computer-readable storage medium is configured to store instructions that, are executed by a processor, cause the processor to perform operations including: generating a composite wafer map including defect points by combining a plurality of wafer level maps generated by measuring a wafer according to respective process operations; sorting the defect points according to defect clusters based on positions of the defect points included in the composite wafer map; and detecting an initial process operation, from among the respective process operations, in which a defect occurred, based on operation information, for each of the defect clusters.

### BRIEF DESCRIPTION OF THE DRAWINGS

The above and other aspects and features will be more apparent from the following description of example embodiments taken in conjunction with the accompanying drawings, in which:

FIG. 1 is a diagram for describing a process of detecting defects of a target wafer, according to one or more example embodiments;

FIG. 2 is a diagram for describing a process of generating a plurality of wafer level maps for a target wafer, according to one or more example embodiments;

FIGS. 3A and 3B are diagrams for describing a wafer level map and a composite wafer map according to one or more example embodiments;

FIG. 4 is a diagram for describing an initial defect point according to one or more example embodiments;

FIG. 5 is a block diagram of a system according to one or more example embodiments;

FIG. 6 is a flowchart of a method of detecting an initial defect point according to one or more example embodiments;

FIG. 7 is a flowchart of a method of sorting defect points according to one or

more example embodiments;

FIG. 8 is a flowchart of a method of searching for adjacent defect points according to one or more example embodiments;

FIG. 9 is a flowchart of a method of detecting an initial defect point according to one or more example embodiments;

FIGS. 10A, 10B, 10C, 10D, 10E, 10F and 10G are diagrams for describing forming of a defect cluster by defect points according to one or more example embodiments;

FIG. 11 is a table for describing an initial defect point of each defect cluster for a target wafer according to one or more example embodiments; and

FIG. 12 is a block diagram of a system according to one or more example embodiments.

### DETAILED DESCRIPTION

Hereinafter, one or more example embodiments will be described in detail with reference to the accompanying drawings. The same reference numerals are used for the same or corresponding elements in descriptions with reference to the drawings, and duplicate descriptions thereof are omitted.

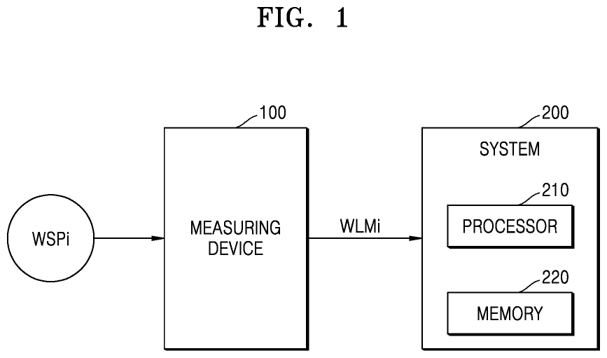

FIG. 1 is a diagram for describing a process of detecting defects of a target wafer WSPi, according to one or more example embodiments.

In a process of manufacturing a semiconductor wafer, several photo processes may be performed on the semiconductor wafer. The semiconductor wafer may be contaminated due to particles caused by friction and vibration during the photo processes. The photo process may be referred to as, for example, photolithography or a photolithography process.

Referring to FIG. 1, the target wafer WSPi may indicate a wafer after a photo process at an i^{th} operation (where i≥1) from among several photo processes performed on a semiconductor wafer. A plurality of defects caused by particles may be in the target wafer WSPi.

A measuring device 100 may measure defects of the semiconductor wafer after each respective photo process performed on the semiconductor wafer is finished. In one or more example embodiments, the measuring device 100 may measure the target wafer WSPi after the i^{th} photo process has been finished, and may deliver a wafer level map WLMi, corresponding to the i^{th} photo process, to a wafer defect detecting system 200. The measuring device 100 may be referred to as a photo level measuring device. In one or more example embodiments, the measuring device 100 measures the target wafer after each photo process, and then generates and transmits a wafer level map to the system 200. Accordingly, after the i^{th} photo process, all of a wafer level map, corresponding to the first photo process, and including additional wafer level map(s) up to the wafer level map WLMi corresponding to the i^{th} photo process, may be stored in the system 200.

The wafer level map WLMi may include data regarding the defect measured from the target wafer WSPi. Data corresponding to each defect may be referred to as a defect point. The wafer level map WLMi may also be referred to as a wafer leveling map. Each defect point may include a position and a height of each defect and operation information of a photo process performed on the target wafer WSPi. As the photo processes are performed, the operation information for corresponding photo operations may have greater values. For example, the third photo process may be performed later in time than the first photo process. Accordingly, an operation information value corresponding to a third photo process may be greater than an operation information value corresponding to the first photo process.

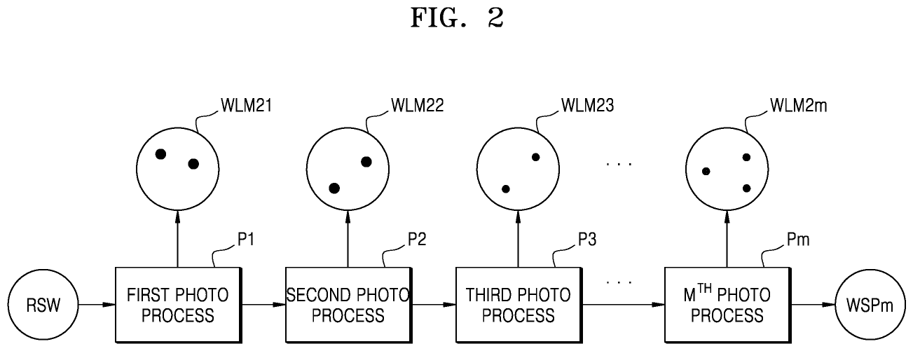

In one or more example embodiments, the operation information may indicate operation information regarding the photo process performed on the target wafer, that is, information indicating an order of the photo processes that were most recently performed. For example, the wafer level map WLMi shown in FIG. 1 may include data indicating that the photo process performed on the target wafer WSPi is the i^{th} operation. As the semiconductor wafer undergoes a plurality of photo processes during manufacture, a plurality of wafer level maps may exist for one wafer. Details thereof will be described below with reference to one or more example embodiments shown in FIG. 2.

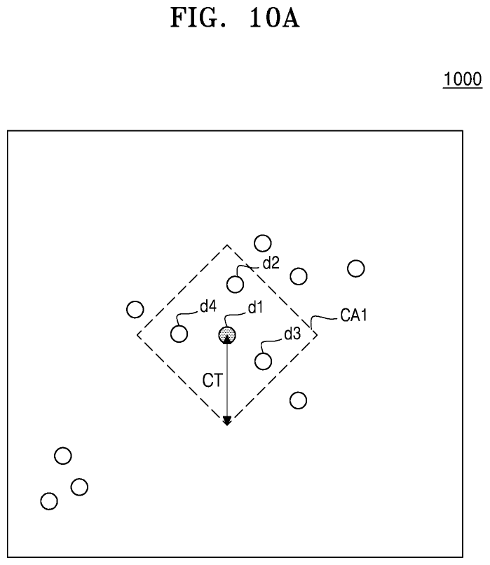

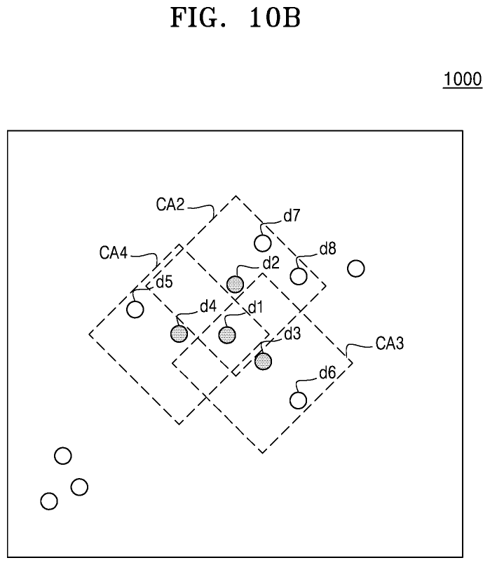

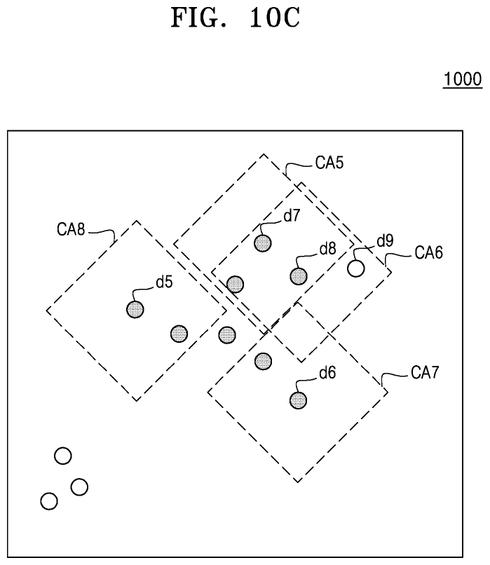

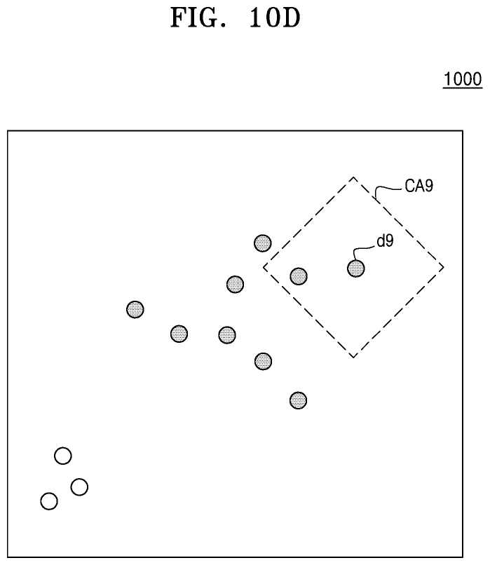

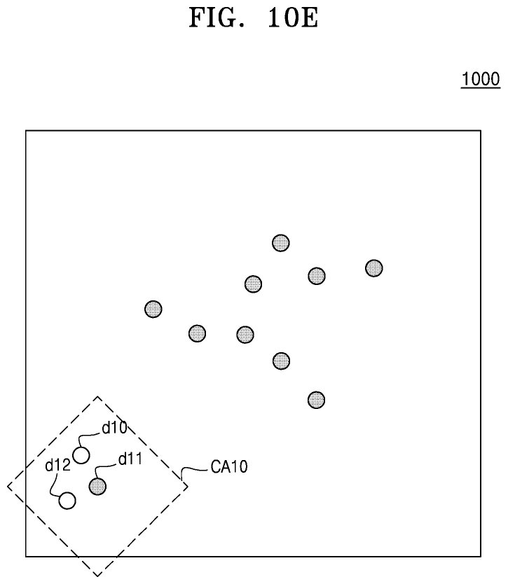

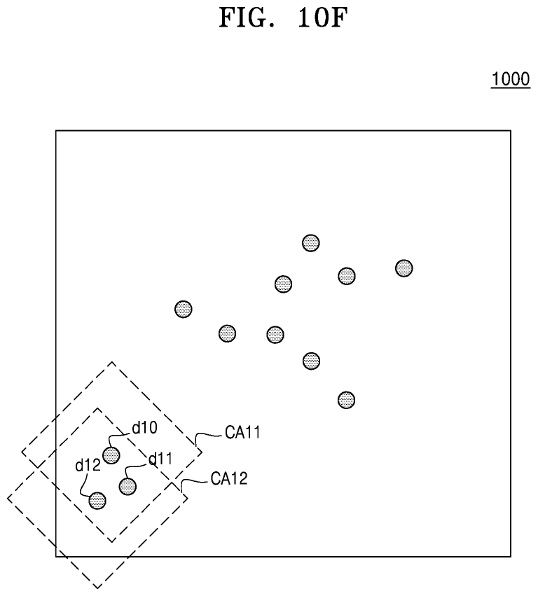

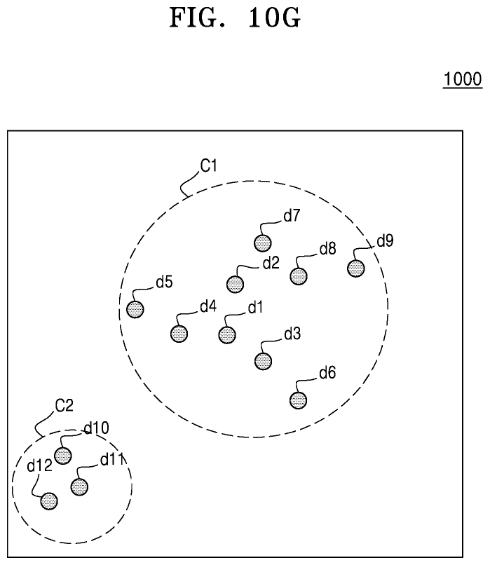

The system 200 may include a system configured to execute a method of detecting wafer defects, according to one or more example embodiments. The system 200 may also be referred to as a wafer defect detecting system. The system 200 may store a plurality of wafer level maps corresponding to all photo processes performed before the i^{th} photo process, including a wafer level map WLMi corresponding to the i^{th} photo process on the target wafer WSPi. The system 200 may combine the plurality of wafer level maps that have been stored. The system 200 may generate a composite wafer map on the basis of the plurality of wafer level maps that have been combined. The composite wafer map may also be referred to as a composite map. The composite wafer map may include a plurality of defect points. The system 200 may sort the plurality of defect points of the composite wafer map into a plurality of clusters, and may detect an initial defect point of the target wafer WSPi on the basis of the defect points that have been sorted. Here, the initial defect point may be referred to as a basic defect point. In one or more example embodiments, the system 200 may sort the defect points of the composite wafer map according to defect clusters, on the basis of a distance between the defect points. A process of forming a defect cluster by a plurality of defect points will be described below with reference to one or more example embodiments shown in FIGS. 10A, 10B, 10C, 10D, 10E, 10F and 10G.

The system 200 may extract a defect point having the least operation information for each defect cluster. The least operation information may indicate operation information corresponding to the earliest photo process in time.

In one or more example embodiments, when there is one defect point extracted from any one defect cluster, that is, one defect point having the least operation information, the extracted defect point may be referred as an initial defect point of the corresponding defect cluster. In an example, when there are a plurality of defect points extracted from any one defect cluster, that is, a plurality of defect points having the least operation information, a defect point having a greatest height from among the extracted defect points may be referred to as the initial defect point of the corresponding defect cluster.

The system 200 may include the processor 210 and the memory 220. For example, the system 200 may include a computing system such as a personal computer, a mobile phone, or a server, or may include a module in which a plurality of processing cores and a memory are mounted on a substrate as independent packages, or may include a system-on-chip (SoC) in which a plurality of processing cores and a memory are mounted in one chip.

The processor 210 may communicate with the memory 220 and execute instructions. In one or more example embodiments, the processor 210 may execute a program stored in the memory 220. The program may include a series of instructions. The processor 210 may include hardware, by which instructions may be independently executed, and may be referred to as an application processor (AP), a communication processor (CP), a central processing unit (CPU), a processor core, a core, or the like.

The processor 210 and the memory 220 may communicate with each other. The memory 220 may store software elements that may be accessed by the processor 210 and are executable by the processor 210. As one or more example embodiments, a software element may include, but is not limited to, a software component, a program, an application, a computer program, an application program, a system program, a software development program, a machine program, an operating system, software, middleware, firmware, a software module, a routine, a subroutine, a function, a method, a procedure, a software interface, an application program interface (API), an instruction set, a computing code, a computer code, a code segment, a computer code segment, a word, a value, a symbol, or a combination of any of the aforementioned.

The memory 220 may include hardware in which information may be stored and which may be accessed by the processor 210. For example, the memory 220 may include, but is not limited to, a read-only memory (ROM), a random-access memory (RAM), a dynamic random access memory (DRAM), a double-data-rate dynamic random access memory (DDR-DRAM), a synchronous dynamic random access memory (SDRAM), a static random access memory (SRAM), a magnetoresistive random access memory (MRAM), a programmable read only memory (PROM), an erasable programmable read only memory (EPROM), an electrically erasable programmable read only memory (EEPROM), a flash memory, a polymer memory, a phase change memory, a ferroelectric memory, a silicon-oxide-nitride-oxide-silicon (SONOS) memory, a magnetic card/disc, an optical card/disc, or any combination thereof.

A method of detecting an initial defect of a wafer, according to one or more example embodiments, may be stored in a computer-readable storage medium, including, but not limited to, a nonvolatile storage medium. The term “computer-readable medium” may include, but is not limited to, a type of medium that may be accessed by a computer, such as a read-only memory (ROM), a random access memory (RAM), a hard disc drive, a compact disc (CD), a digital video disc (DVD), or any other type of memory. A “non-transitory” computer-readable medium may exclude wired, wireless, optical, or other communication links configured to transfer transitory electric or other signals, and may include, but is not limited to, a medium in which data may be consistently stored or a medium which may store and overwrite data, such as a rewritable optical disc or an erasable memory device.

FIG. 2 is a diagram for describing a process of generating a plurality of wafer level maps with respect to a target wafer WSPm, according to one or more example embodiments. FIG. 2 may be described with reference to one or more example embodiments shown in FIG. 1, and repeated descriptions have been omitted.

Several photo processes may be performed on a semiconductor wafer RSW. For example, referring to one or more example embodiments shown in FIG. 2, a first photo process P1 to an m^{th} photo process Pm may be performed on the semiconductor wafer RSW. In other words, m (where m≥1) photo processes may be performed on the semiconductor wafer RSW.

The target wafer WSPm may indicate the semiconductor wafer after the first photo process P1 and after the m^{th} photo process Pm.

The measuring device 100 may measure the semiconductor wafer RSW after each photo process that is performed on the semiconductor wafer RSW, to thereby generate a wafer level map. In one or more example embodiments, the measuring device 100 may measure the semiconductor wafer RSW after the first photo process P1 to generate a first wafer level map WLM21. The measuring device 100 may measure the semiconductor wafer RSW after a second photo process P2 to generate a second wafer level map WLM22. The measuring device 100 may measure the semiconductor wafer RSW after a third photo process P3 to generate a third wafer level map WLM23. The measuring device 100 may measure the semiconductor wafer RSW after the m^{th} photo process Pm to generate an m^{th} wafer level map WLM2m.

The first wafer level map WLM21 may include defect points measured after the first photo process P1. The second wafer level map WLM22 may include defect points measured after the second photo process P2. The third wafer level map WLM23 may include defect points measured after the third photo process P3. The mth wafer level map WLM2m may include defect points measured after the m^{th} photo process Pm. The system 200 may generate the composite wafer map by combining the first wafer level map WLM21 to the mth wafer level map WLM2m.

In one or more example embodiments, due to various semiconductor processes that may be performed between the first photo process P1 and the second photo process P2, the defect points included in the first wafer level map WLM21 may be included in, or excluded from, the second wafer level map WLM22. Likewise, the defect points included in the first wafer level map WLM21 may be included in the third wafer level map WLM23, even when excluded from the second wafer level map WLM22.

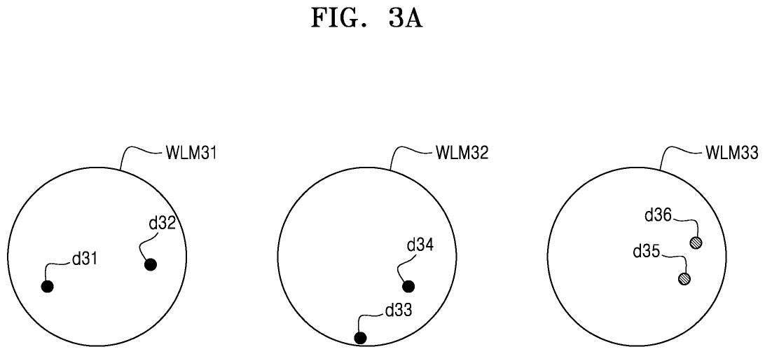

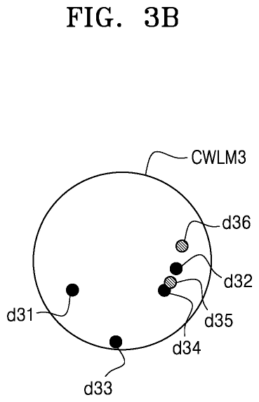

According to one or more example embodiments, the initial defect point may be detected from among the plurality of defect points of the target wafer WSPm, based on the composite wafer map obtained by accumulative composition of the wafer level maps. Therefore, according to one or more example embodiments, the initial defect point generated on the target wafer WSPm may be detected even when some defect points are missing from a certain wafer level map. The composite wafer map will be described below with reference to one or more example embodiments shown in FIG. 3B.

FIGS. 3A and 3B are diagrams for describing wafer level maps (e.g., a first wafer level map WLM31, a second wafer level map WLM32, and a third wafer level map WLM33) and a composite wafer map CWLM3 according to one or more example embodiments. One or more example embodiments shown in FIGS. 3A and 3B may be described with reference to FIGS. 1 and 2, and repeated descriptions have been omitted. In FIGS. 3A and 3B, according to one or more example embodiments, three photo processes have been performed on a semiconductor wafer. Therefore, a target wafer subject to initial defect detection may include a wafer on which a third photo process has been performed. Hereinafter, three photo processes performed on the semiconductor wafer is merely an example, and less or more photo processes may also be performed according to one or more example embodiments.

FIG. 3A is a diagram of three wafer level maps (i.e., a first wafer level map WLM31, a second wafer level map WLM32, and a third wafer level map WLM33) formed after three photo processes on the semiconductor wafer. Each of the wafer level maps (i.e., the first wafer level map WLM31, the second wafer level map WLM32, and the third wafer level map WLM33) may include a defect point. The defect point may include a position, a height, and operation information of the defect. The position of the defect may indicate a coordinate of the defect on the wafer. The height of the defect may indicate the degree of contamination caused due to a particle on the wafer, that is, a size of a hot spot. The height may be referred to as an abnormal value indicating whether the defect is abnormal. The operation information of the defect may indicate a photo process at which the defect has been measured. For example, according to one or more example embodiments, when the defect has occurred in a first photo process, the operation information may include a first value. For another example, according to one or more example embodiments, when the defect has occurred in a fourth photo process, the operation information may include a fourth value.

The first wafer level map WLM31 may include defect points of the semiconductor wafer after the first photo process. The first wafer level map WLM31 may include a first defect point d31 and a second defect point d32. The first wafer level map WLM31 may include a position, a height, and operation information for each of the first defect point d31 and the second defect point d32. In one or more example embodiments, the operation information of the first defect point d31 and the second defect point may include the first value.

The second wafer level map WLM32 may include defect points of the semiconductor wafer after the second photo process. The second wafer level map WLM32 may include a third defect point d33 and a fourth defect point d34. The second wafer level map WLM32 may include a position, a height, and operation information for each of the third defect point d33 and the fourth defect point d34. In one or more example embodiments, the operation information of the third defect point d33 and the fourth defect point may include a second value.

The third wafer level map WLM33 may include defect points of the semiconductor wafer after the third photo process. The third wafer level map WLM33 may include a fifth defect point d35 and a sixth defect point d36. The third wafer level map WLM33 may include a position, a height, and operation information of each of the fifth defect point d35 and the sixth defect point d36. In one or more example embodiments, the operation information of the fifth defect point d35 and the sixth defect point d36 may include a third value.

FIG. 3B is a diagram for describing a composite wafer map according to one or more example embodiments. The system 200 may generate the composite wafer map CWLM3 by combining the first wafer level map WLM31, the second wafer level map WLM32, and the third wafer level map WLM33.

The composite wafer map CWLM3 may include the positions, heights, and the operation information of the first defect point d31, the second defect point d32, the third defect point d33, the fourth defect point d34, the fifth defect point d35, and the sixth defect point d36.

The system 200 may sort the defect points of the composite wafer map CWLM3 according to defect clusters. The system 200 may detect the initial defect point of the target wafer based on the defect points that have been sorted.

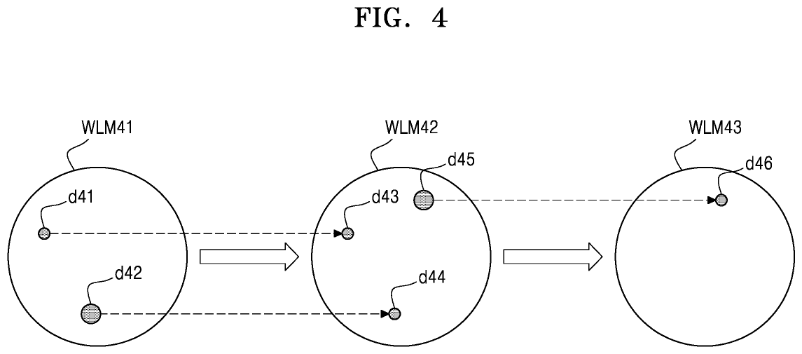

FIG. 4 is a diagram for describing an initial defect point according to one or more example embodiments. FIG. 4 may be described with reference to FIGS. 1, 2, 3A and 3B, and duplicate descriptions may be omitted. In FIG. 4, according to one or more example embodiments, three photo processes have been performed on the semiconductor wafer. Three photo processes being performed on the semiconductor wafer is merely an example, and less or more than three photo processes may also be performed according to one or more example embodiments.

A first wafer level map WLM41 may include defect points of the semiconductor wafer after the first photo process P1. The first wafer level map WLM41 may include a first defect point d41 and a second defect point d42. The first wafer level map WLM41 may include a position, a height, and operation information of each of the first defect point d41 and the second defect point d42. In one or more example embodiments, the operation information of the first defect point d41 and the second defect point d42 may include the first value.

A second wafer level map WLM42 may include defect points of the semiconductor wafer after the second photo process P2. The second wafer level map WLM42 may include a third defect point d43, a fourth defect point d44, and a fifth defect point d45. The second wafer level map WLM42 may include a position, a height, and operation information of each of the third defect point d43, the fourth defect point d44, and the fifth defect point d45. In one or more example embodiments, the operation information of the third defect point d43, the fourth defect point d44, and the fifth defect point d45 may include the second value.

A third wafer level map WLM43 may include defect points of the semiconductor wafer after the third photo process. The third wafer level map WLM43 may include a sixth defect point d46. The third wafer level map WLM43 may include a position, a height, and operation information of the sixth defect point d46. In one or more example embodiments, the operation information of the sixth defect point d46 may include the third value.

As described above with reference to one or more example embodiments shown in FIG. 3B, the system 200 may generate the composite wafer map by combining the first wafer level map WLM41, the second wafer level map WLM42, and the third wafer level map WLM43. The system 200 may detect the initial defect point from among the first defect point d41, the second defect point d42, the third defect point d43, the fourth defect point d44, the fifth defect point d45 and the sixth defect point d46, based on the composite wafer map. The defect points existing in the composite wafer map may form defect clusters, and the initial defect points may exist in each of the defect clusters. Accordingly, one or more initial defect points may exist in one composite wafer map.

In one or more example embodiments, the first defect point d41 and the third defect point d43 may be at a same position, or at positions adjacent to each other. Therefore, when the system 200 sorts the defect points included in the composite wafer map, the first defect point d41 and the third defect point d43 may be sorted into a first cluster. The first defect point d41 may have operation information corresponding to an operation prior to that of the third defect point d43. Accordingly, the first defect point d41 may include an initial defect point of the first cluster. If the operation information of the first defect point d41 includes the first value, the defects included in the first cluster may include the defects that have occurred in the first photo process P1.

In one or more example embodiments, the second defect point d42 and the fourth defect point d44 may be at a same position, or at positions adjacent to each other. Therefore, when the system 200 sorts the defect points included in the composite wafer map, the second defect point d42 and the fourth defect point d44 may be sorted into a second cluster. The second defect point d42 may have operation information corresponding to an operation prior to that of the fourth defect point d44. Accordingly, the second defect point d42 may include an initial defect point of the second cluster. If the operation information of the second defect point d42 includes the first value, the defect points included in the second cluster may include the defects that have occurred in the first photo process P1.

In one or more example embodiments, the fifth defect point d45 and the sixth defect point d46 may be at a same position, or at positions adjacent to each other. Accordingly, when the system 200 sorts the defect points included in the composite wafer map, the fifth defect point d45 and the sixth defect point d46 may be sorted into a third cluster. The fifth defect point d45 may have operation information corresponding to an operation prior to that of the sixth defect point d46. Accordingly, the fifth defect point d45 may include an initial defect point of the third cluster. If the operation information of the fifth defect point d45 includes the second value, the defects included in the third cluster may include the defects that have occurred in the second photo process P2.

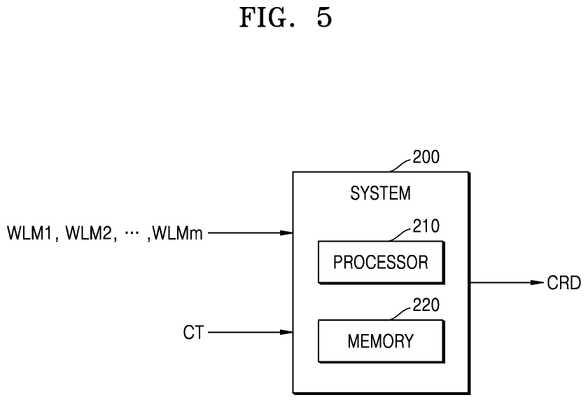

FIG. 5 is a block diagram of the system 200 according to one or more example embodiments. FIG. 5 may be described with reference to one or more example embodiments shown in FIG. 1, and duplicate descriptions have been omitted.

The system 200 may include the processor 210 and the memory 220. The system 200 may receive a first wafer level map WLM1 to an m^{th} wafer level map WLMm. The system 200 may generate a composite wafer map by combining the first wafer level map WLM1 to the m^{th} wafer level map WLMm that have been received.

The system 200 may receive a critical threshold value CT. The critical threshold value CT may include a value input by a user. Therefore, according to one or more example embodiments, a method of clustering defects may be defined according to requirements of the user. The system 200 may compare a distance between the defect points and the critical threshold value CT to determine whether the defect points correspond to defect points adjacent to each other.

The system 200 may calculate a distance between the defect points existing in the composite wafer map, and may determine whether there is an adjacent defect point for each defect point, based on the calculated distance and the critical threshold value CT received. In one or more example embodiments, the distance between the defect points existing in the composite wafer map may be calculated using a vector based on a position of any one defect point and a position of another defect point. For example, an Lₚ norm value of the vector may be used to determine whether the defect points are defect points adjacent to each other. The Lₚ norm value may be calculated according to Equation 1 as follows: In Equation 1, x may indicate an expression in a vector for a distance from the reference defect point to another defect point. In Equation 1, k may indicate an index corresponding to each element of x.

$${L}_{p} = {‖ x ‖}_{p} = {( {\sum }_{k} {\vert {x}_{k} \vert}^{p} )}^{\frac{1}{p}} \qquad [ Equation 1 ]$$

The system 200 may determine a p value of the Lₚ norm in response to a user input received. Therefore, according to one or more example embodiments, the method of clustering the defects may be defined with convenience and consistency according to requirements of the user. Hereinafter, it may be assumed that the p value is 1. That is, it may be assumed that the Lₚ norm is the L₁ norm. The L₁ norm may be referred to as a Manhattan norm. That the Lₚ norm is the L₁ norm is merely an example, and the Lₚ norm may be calculated in various schemes according top values. For example, when the p value is 2, the Lₚ norm may include the L₂ norm, and the L₂ norm may be referred to as an Euclidean norm. For example, the Lₚ norm may include a max norm.

With respect to the plurality of defect points included in the composite wafer map, the system 200 may sort the plurality of defect points according to defect clusters while comparing the distance between the defect points with the critical threshold value CT. At least one or more clusters may exist on the composite wafer map.

The system 200 may sort the plurality of defect points included in the composite wafer map according to the defect clusters, and may detect an initial defect point for each defect cluster. The system 200 may generate a defect cluster set CRD including the defect clusters. The defect cluster set CRD may include the defect clusters existing in the composite wafer map. Each of the defect clusters may include a position, a height, operation information, and a cluster ID for a defect point belonging to each defect cluster. Here, the cluster ID may include data indicating a defect cluster in which each defect point is included. In one or more example embodiments, the system 200 may add the defect points to the each defect cluster by allocating the cluster ID's to each of the defect points.

The system 200 may detect the initial defect point for each defect cluster, based on the defect cluster set CRD.

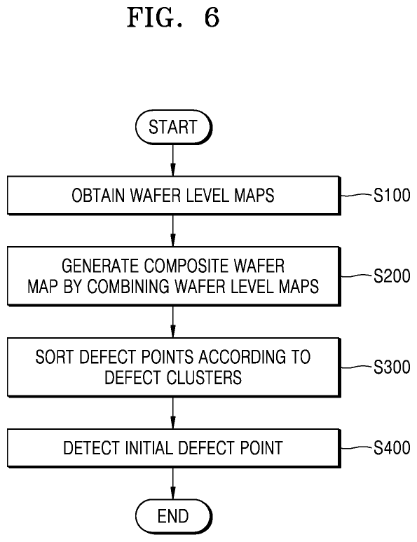

FIG. 6 is a flowchart of a method of detecting an initial defect point according to one or more example embodiments. More particularly, the flowchart shown in FIG. 6 illustrates a method of detecting an initial defect point of the target wafer by the system 200 according to one or more example embodiments shown in FIG. 5. FIG. 6, which may be described with reference to one or more example embodiments shown in FIGS. 1 and 5, and duplicate descriptions have been omitted. Hereinafter, it may be assumed that m (wherein m≥1) photo processes have been performed on the target wafer to detect defects thereof.

In operation S100, the system 200 may obtain the first wafer level map WLM1 to the m^{th} wafer level map WLMm for the target wafer. In one or more example embodiments, the first wafer level map WLM1 to the m^{th} wafer level map WLMm may be transferred to the system 200 by the measuring device 100.

In operation S200, the system 200 may generate the composite wafer map by combining all of the first wafer level map WLM1 to the m^{th} wafer level map WLMm. In one or more example embodiments, the composite wafer map may include data obtained by obtaining m wafer level maps. Accordingly, the composite wafer map may include all defect points that have occurred in the target wafer due to the first photo process P1 to the m^{th} photo process Pm.

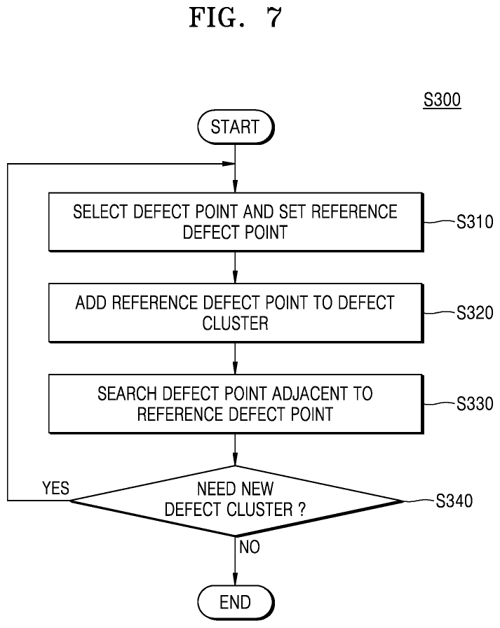

In operation S300, the system 200 may sort the plurality of defect points included in the composite wafer map. In detail, the system 200 may sort the defect points according to defect clusters, based on positions of the defect points included in the composite wafer map. The defect points that have been sorted may form a cluster. The system 200 may generate a defect cluster set. Details of operation S300 are described in greater detail below with reference to one or more example embodiments shown in FIG. 7.

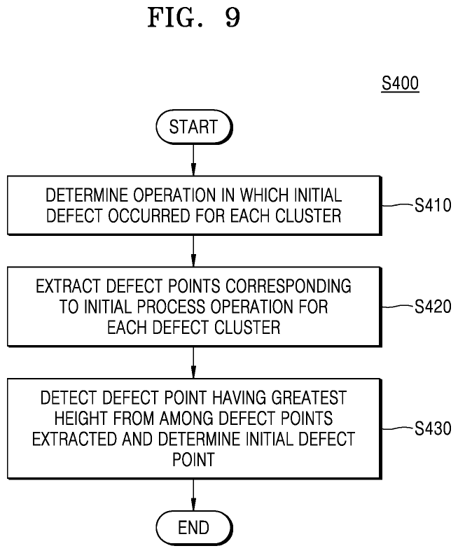

In operation S400, the system 200 may detect an initial process operation in which defects have occurred for each defect cluster, and may defect the initial defect point of each defect cluster based on information regarding the initial process operation that has been detected. Details of operation S400 are described in greater detail below with reference to one or more example embodiments shown in FIG. 9.

FIG. 7 is a flowchart of a method of sorting defect points according to one or more example embodiments. In detail, the flowchart shown in FIG. 7 is a flowchart for describing detailed operations in operation S300 of one or more example embodiments shown in FIG. 6. FIG. 7, which may be described with reference to one or more example embodiments shown in FIGS. 1, 5, and 6, and duplicate descriptions have been omitted.

In operation S310, the system 200 may arbitrarily select any one defect point from among the defect points included in the composite wafer map and may set the selected defect point as a reference defect point. In one or more example embodiments, the reference defect point that has been initially selected may be referred to as a first defect point.

In operation S320, the system 200 may add the reference defect point selected in operation S310 to the defect cluster. In one or more example embodiments, the system 200 may add the first defect point to the first defect cluster. Here, that the first defect point is added to the first defect cluster may indicate that the first defect point includes the defect point included in the first defect cluster.

In operation S330, the system 200 may search for a detect point adjacent to the reference defect point. In detail, the system 200 may calculate a distance between the reference defect point and each defect point included in the composite wafer map. According to one or more example embodiments, other defect points may include a defect point not included in any defect cluster from among the defect points included in the composite wafer map. Such defect points may be referred to, for example, as unsorted defect points, non-clustered defect points, or defect points to which a cluster ID is not allocated.

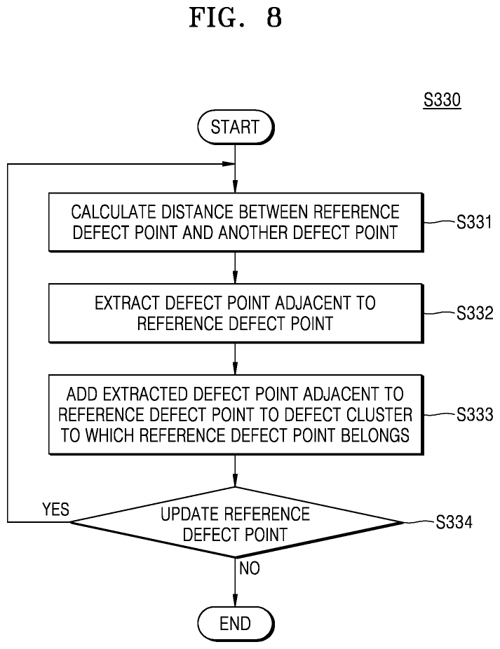

After calculating the distance, the system 200 may extract the defect points in a distance less than the critical threshold value CT from the reference defect point. According to one or more example embodiments, the defect points that have been extracted may be referred to as adjacent defect points or neighboring defect points. The system 200 may add the extracted adjacent defect points to a defect cluster that is the same as the defect cluster to which the reference defect point belongs. For example, when the reference defect point belongs to the first defect cluster, the extracted adjacent defect points may also belong to the first defect cluster. The system 200 may repeat operation S330 using the extracted adjacent defect points as new reference defect points. Here, operation S330 may be repeatedly performed until no more new adjacent defect points are extracted. Details of operation S330 are described in greater detail below with reference to one or more example embodiments shown in FIG. 8.

In operation S340, the system 200 may determine whether the composite wafer map is in need of a new defect cluster. In detail, the system 200 may determine whether there are unsorted defect points that have not been sorted in operations S320 and S330 from among the defect points included in the composite wafer map. When there is any one unsorted defect point, the system 200 may select any one of the unsorted defect points. The system 200 may update the reference defect point such that the selected defect point is the reference defect point, and may repeatedly perform operations S310 to S330. In one or more example embodiments, the additionally selected defect point may be referred to as a second defect point.

In one or more example embodiments, it may be assumed that a plurality of unsorted defect points still exist in the composite wafer map after performing operation S330. The system 200 may arbitrarily select any one of the plurality of unsorted defect points. The system 200 may update the reference defect point such that the defect point selected at this time is a reference defect point. The system 200 may sort the updated reference defect point to a new defect cluster. For example, when only the first defect cluster exists in the composite wafer map when operation S340 is performed, the new defect cluster may include a same defect cluster. For example, when the first defect cluster to a n-1^{th} defect cluster exist in the composite wafer map when operation S340 is performed, a new defect cluster may include an nth defect cluster (where n≥1).

When all of the defect points included in the composite wafer map have been completely sorted, the system 200 may generate a defect cluster set.

FIG. 8 is a flowchart of a method of searching for adjacent defect points according to one or more example embodiments. In detail, the flowchart shown in FIG. 8 is a flowchart for describing detailed operations in operation S330 shown in FIG. 7 according to one or more example embodiments. FIG. 8 may be described with reference to one or more example embodiments shown in FIGS. 1, 6, and 7, and duplicate descriptions have been omitted.

In operation S331, the system 200 may calculate the distance between the reference defect point and another defect point. According to one or more example embodiments, the other defect points may include defect points not belonging to any defect cluster. In one or more example embodiments, it may be assumed that the first defect point corresponds to the reference defect point. The system 200 may calculate a distance between the first defect point and the defect point not belonging to any defect cluster from among the plurality of defect points included in the composite wafer map. According to one or more example embodiments, the distance may be calculated using the Lₚ norm in Equation 1.

In operation S332, the system 200 may extract defect points adjacent to the reference defect point. In detail, from among the plurality of defect points included in the composite wafer map, the system 200 may extract defect points of which distances from the reference defect point calculated in operation S331 are less than the critical threshold value CT.

In one or more example embodiments, the critical threshold value CT may include a value input from an external source and may also include a value pre-input to the system 200. The user may modify the critical threshold value CT according to various occasions to control the system 200 to cluster the defect points.

In operation S333, the system 200 may add the extracted adjacent defect point to a defect cluster that is the same as the defect cluster to which the reference defect point belongs. For example, when the reference defect point belongs to the first defect cluster, the extracted adjacent defect points may also belong to the first defect cluster. By way of further example, when the reference defect point belongs to the second defect cluster, the extracted adjacent defect points may also belong to the second defect cluster.

In operation S334, the system 200 may update the extracted adjacent defect points as new reference defect points. The system 200 may repeatedly perform operation S330 based on the updated reference defect points. According to one or more example embodiments, the system 200 may repeat operation S330 until no more new adjacent defect point is extracted.

FIG. 9 is a flowchart of a method of detecting an initial defect point according to one or more example embodiments. In detail, the flowchart shown in FIG. 9 is a flowchart for describing detailed operations in operation S400 of one or more example embodiments shown in FIG. 6. FIG. 9, which may be described with reference to one or more example embodiments shown in FIGS. 1 and 6, and duplicate descriptions have been omitted.

In operation S410, the system 200 may determine an initial process operation, in which initial defect(s) have occurred, for each defect cluster. In detail, the system 200 may detect the initial process operation, in which initial defect(s) have occurred, for each defect cluster, using the sorted defect points included in the composite wafer map.

In one or more example embodiments, it may be assumed that the first defect cluster includes the first defect point, the second defect point, and the third defect point. Furthermore, it may also be assumed that the operation information of the first defect point and the second defect point includes the first value, and the operation information of the third defect point includes the second value. According to one or more example embodiments, from among the defect points belonging to the first defect cluster, the first defect point and the second defect point have least operation information. Accordingly, initial process operation information corresponding to the first defect cluster may include the first value.

In operation S420, the system 200 may extract defect points corresponding to the initial process operation for each defect cluster, based on the initial process operation information that has been detected.

In one or more example embodiments, it may be assumed that the initial process operation information of the first defect cluster has been detected as the first value in operation S410. The first value may correspond to the first photo process. Accordingly, the system 200 may determine that the defects related to the first cluster have occurred due to the first photo process. From among the defect points included in the first defect cluster, the system 200 may extract the defect points corresponding to the first photo process.

In operation S430, the system 200 may detect a defect point having a greatest height from among the defect points extracted in operation S420. The defect point having the greatest height that has been detected may be referred to as the initial defect point of the corresponding defect cluster. The user may find a process facility with a problem at an early stage and take action, based on process operation information and the position included in the initial defect point that has been detected.

In one or more example embodiments, it may be assumed that the first wafer level map includes the first defect point and the second defect point. According to one or more example embodiments it may be assumed that the first defect point and the second defect point belong to the first defect cluster. According to one or more example embodiments, it may be assumed that the first defect point has a height greater than a height of the second defect point. In this case, because the first defect point has the greatest height in the first wafer level map, the first defect point may include the initial defect point of the first wafer level map. Accordingly, the system 200 may detect the first defect point that is the initial defect point of the first wafer level map. Based on the operation information included in the initial defect point that has been detected, the user may determine that the first defect cluster has been caused due to the facility related to the first photo process. Furthermore, the user may take action with respect to a portion of the facility in the first photo process, which corresponds to the position of the initial defect point, based on information regarding the position of the initial defect point. As described above, by tracking a process facility causing defects on the semiconductor wafer at an early stage, the productivity and quality of a semiconductor product may be improved, and by doing so, the yield of the semiconductor product may increase.

FIGS. 10A, 10B, 10C, 10D, 10E, 10F and 10G are diagrams for describing the forming of defect clusters by defect points according to one or more example embodiments. In detail, FIGS. 10A, 10B, 10C, 10D, 10E, 10F and 10G are diagrams for describing one or more example embodiments for sorting the defect points on a composite wafer map 1000 by the system 200 according to defect clusters in operation S300 according to one or more example embodiments shown in FIG. 6. Moreover, FIGS. 10A, 10B, 10C, 10D, 10E, 10F and 10G may be described with reference to one or more example embodiments shown in FIGS. 1 and 6, 7 and 8, and duplicate descriptions have been omitted.

According to one or more example embodiments, it may be assumed that the Lₚ norm used when calculating the distance between the reference defect point and another defect point is L₁ norm. However, is the aforementioned may be merely an example, and the p value may be modified according to the needs of the user.

Referring to one or more example embodiments shown in FIG. 10A, a plurality of defect points may exist on the composite wafer map 1000. In this case, each defect point may be not included in any defect cluster. The system 200 may select a first defect point d1 from among the defect points on the composite wafer map 1000. The system 200 may set the first defect point d1 as a reference defect point and add the first defect point d1 to a first defect cluster C1.

The system 200 may search for adjacent defect points with reference to the first defect point d1. According to one or more example embodiments, the system 200 may calculate distances from the first defect point d1 to other defect points using the L₁ norm, and may determine the defect points having a distance within the critical threshold value CT from the first defect point d1 as being adjacent defect points.

In one or more example embodiments, defect points belonging to a first area CA1 may correspond to the defect points adjacent to the first defect point d1. Accordingly, the defect points adjacent to the first defect point d1, that is the reference defect point shown in FIG. 10A, may include a second defect point d2, a third defect point d3, and a fourth defect point d4.

Referring to one or more example embodiments shown in FIG. 10B, the system 200 may update the reference defect point such that the second defect point d2, the third defect point d3, and the fourth defect point d4, which have been determined as the defect points adjacent to the first defect point in FIG. 10A, as being new, or updated, reference defect points.

The system 200 may add the updated reference defect points, i.e., the second defect point d2, the third defect point d3, and the fourth defect point d4, to the first defect cluster C1. The system 200 may search for a defect point adjacent to each of the second defect point d2, the third defect point d3, and the fourth defect point d4.

In one or more example embodiments, the defect points already belonging to any defect cluster may be excluded from search targets. For example, the first defect point d1 already belongs to the first defect cluster C1, and thus may be excluded from the search targets.

In one or more example embodiments, the defect points belonging to a second area CA2 may correspond to the defect points adjacent to the second defect point d2. Accordingly, defect points adjacent to the second defect point d2, that is one of the reference defect points in FIG. 10B, may include a seventh defect point d7 and an eighth defect point d8.

In one or more example embodiments, defect points belonging to a third area CA3 may correspond to defect points adjacent to the third defect point d3. Accordingly, a defect point adjacent to the third defect point d3, that is one of the reference defect points in FIG. 10B, may include a sixth defect point d6.

In one or more example embodiments, defect points belonging to a fourth area CA4 may correspond to defect points adjacent to the fourth defect point d4. Accordingly, a defect point adjacent to the fourth defect point d4, that is one of the reference defect points in FIG. 10B, may include a fifth defect point d5.

Referring to one or more example embodiments shown in FIG. 10C, the system 200 may update the reference defect points such that the fifth defect point d5, the sixth defect point d6, the seventh defect point d7, and the eighth defect point d8, which have been determined as the defect points adjacent to the reference defect points in FIG. 10B, are new or updated reference defect points.

The system 200 may add the updated reference defect points, i.e., the fifth defect point d5, the sixth defect point d6, the seventh defect point d7, and the eighth defect point d8, to the first defect cluster C1. The system 200 may search for a defect point adjacent to each of the fifth defect point d5, the sixth defect point d6, the seventh defect point d7, and the eighth defect point d8.

In one or more example embodiments, the defect points already included in any defect cluster may be excluded from search targets. For example, the second defect point d2 may already belong to the first defect cluster C1, and thus the second defect point d2 may be excluded from the search targets.

In one or more example embodiments, the defect points belonging to a fifth area CA5 may correspond to defect points adjacent to the seventh defect point d7. Accordingly, there are no more defect points not belonging to any defect cluster while being adjacent to the seventh defect point d7, that is one of the reference defect points in FIG. 10C, and thus, the system 200 may finish the search regarding the seventh defect point d7.

In one or more example embodiments, defect points belonging to a sixth area CA6 may correspond to defect points adjacent to the eighth defect point d8. Accordingly, a defect point adjacent to the eighth defect point, that is one of the reference defect points in FIG. 10C, may include a ninth defect point d9.

In one or more example embodiments, defect points belonging to a seventh area CA7 may correspond to defect points adjacent to the sixth defect point d6. Accordingly, there are no more defect points not belonging to any defect cluster while being adjacent to the sixth defect point d6, that is one of the reference defect points in FIG. 10C, and thus, the system 200 may finish the search regarding the sixth defect point d6.

In one or more example embodiments, the defect points belonging to an eighth area CA8 may correspond to defect points adjacent to the fifth defect point d5. Accordingly, there are no more defect points not belonging to any defect cluster while being adjacent to the fifth defect point d5, that is one of the reference defect points in FIG. 10C, and thus, the system 200 may finish the search regarding the fifth defect point d5.

Referring to one or more example embodiments shown in FIG. 10D, the system 200 may update the reference defect points such that a ninth defect point d9, which has been determined as a defect point adjacent to each of the reference defect points shown in FIG. 10C, is a new or updated reference defect point.

The system 200 may add the ninth defect point d9, i.e., the updated reference defect point, to the first defect cluster C1. The system 200 may search for defect points adjacent to the ninth defect point d9.

In one or more example embodiments, the defect points already included in any defect cluster may be excluded from search targets. For example, the eighth defect point d8 already belongs to the first defect cluster C1, and thus may be excluded from the search target.

In one or more example embodiments, defect points belonging to a ninth area CA9 may correspond to defect points adjacent to the ninth defect point d9. Accordingly, there are no more defect points not belonging to any defect cluster while being adjacent to the ninth defect point in FIG. 10D, and thus, the system 200 may finish search regarding the ninth defect point d9.

Referring to one or more example embodiments shown in FIG. 10E, there still may be defect points (which may be referred to as unsorted defect points or defect points to which cluster ID's are not allocated) not belonging to any defect cluster on the composite wafer map 1000. For example, a tenth defect point d10, an eleventh defect point d11, and a twelfth defect point d12 may not belong to the first defect cluster C1.

According to one or more example embodiments, the system 200 may perform operations in operation S340 of one or more example embodiments shown in FIG. 7. In one or more example embodiments, the system 200 may select any one of the unsorted defect points existing on the composite wafer map 1000, and may update the selected defect point as being a new reference defect point.

In one or more example embodiments, the system 200 may update the eleventh defect point d11 as being a new reference defect point. The system 200 may add the eleventh defect point d11 to a second defect cluster C2. The system 200 may search defect points adjacent to the eleventh defect point d11. Defect points belonging to a tenth area CA10 may correspond to the defect points adjacent to the eleventh defect point d11. Accordingly, defect points adjacent to the eleventh defect point d11, that is the reference defect point in FIG. 10E, may include the tenth defect point d10 and the twelfth defect point d12.

Referring to one or more example embodiments shown in FIG. 10F, the system 200 may update the reference defect points such that the tenth defect point d10 and the twelfth defect point d12, which have been determined as the defect points adjacent to the reference defect points in FIG. 10F, are new or updated reference defect points.

The system 200 may add the updated reference defect points, i.e., the tenth defect point d10 and the twelfth defect point d12, to the second defect cluster C2. The system 200 may search for defect points adjacent to the tenth defect point d10 and the twelfth defect point d12.

In one or more example embodiments, defect points belonging to an eleventh area CA11 may correspond to the defect points adjacent to the tenth defect point d10. Accordingly, there are no more defect points not belonging to any defect cluster while being adjacent to the tenth defect point d10 shown in FIG. 10F, and thus, the system 200 may finish the search regarding the tenth defect point d10.

In one or more example embodiments, defect points belonging to a twelfth area CA12 may correspond to the defect points adjacent to the twelfth defect point d12. Accordingly, there are no more defect points not belonging to any defect cluster while being adjacent to the twelfth defect point d12, and thus, the system 200 may finish the search regarding the twelfth defect point d12.

FIG. 10G may illustrate a state in which all of the defect points existing on the composite wafer map 1000 are sorted, according to one or more example embodiments. For example, the defect points belonging to the first defect cluster C1 may include the first defect point d1 to the ninth defect point d9. The defect points belonging to the second defect cluster C2 may include the tenth defect point d10 to the twelfth defect point d12.

In the system 200 according to one or more example embodiments, when all of the defect points on the composite wafer map 1000 are sorted, as shown according to one or more example embodiments in FIG. 10G, the composite wafer map 1000 may be referred to as a sorted composite wafer map. The system 200 may generate a defect cluster set on the basis of the sorted composite wafer map.

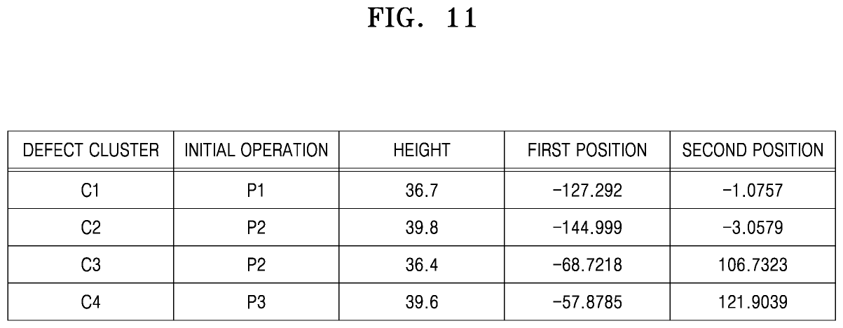

FIG. 11 is a table for describing an initial defect point for each defect cluster for the target wafer, according to one or more example embodiments. In detail, FIG. 11 illustrates one or more example embodiments in which the system 200 has sorted the defect points included in the composite wafer map corresponding to the target wafer and has then detected the initial defect point for each defect cluster. FIG. 11 may be described with reference to one or more example embodiments shown in FIGS. 1 and 9, and duplicate descriptions have been omitted.

According to one or more example embodiments, it may be assumed that the composite wafer map includes four defect clusters in total. For example, the four defect clusters may include the first defect cluster C1, the second defect cluster C2, a third defect cluster C3, and a fourth defect cluster C4.

The initial defect point may include a defect cluster to which each initial defect point belongs, an initial photo process operation, a height, a first position, and a second position. For example, the first position may indicate an x coordinate on the composite wafer map, and the second position may indicate a y coordinate on the composite wafer map. In one or more example embodiments, to which defect cluster each initial defect point belongs may be distinguished by a defect cluster ID.

In one or more example embodiments, at least one defect point may exist in the first defect cluster C1. The system 200 may detect the initial defect point from among the defect points included in the first defect cluster C1. The initial defect point of the first defect cluster C1 may include a defect point having the least operation information from among the defect points belonging to the first defect cluster C1. According to one or more example embodiments, the least operation information may indicate operation information corresponding to an earliest photo process. In the first defect cluster C1, the earliest photo process corresponding to the least operation information may include the first photo process P1. When there are a plurality of defect points having the least operation information, the initial defect point of the first defect cluster C1 may include a defect point having a greatest height from among the defect points having the least operation information.

In one or more example embodiments, at least one defect point may exist in the second defect cluster C2. The system 200 may detect an initial defect point from among the defect points included in the second defect cluster C2. The initial defect point of the second defect cluster C2 may include a defect point having the least operation information from among the defect points belonging to the second defect cluster C2. In the second defect cluster C2, the earliest photo process corresponding to the least operation information may include the second photo process P2. When there are a plurality of defect points having the least operation information, the initial defect point of the second defect cluster C2 may include a defect point having a greatest height from among the defect points having the least operation information.

In one or more example embodiments, at least one defect point may exist in the third defect cluster C3. The system 200 may detect an initial defect point from among the defect points included in the third defect cluster C3. The initial defect point of the third defect cluster C3 may include a defect point having the least operation information from among the defect points belonging to the third defect cluster C3. In the third defect cluster C3, the earliest photo process corresponding to the least operation information may include the second photo process P2. When there are a plurality of defect points having the least operation information, the initial defect point of the third defect cluster C3 may include a defect point having a greatest height from among the defect points having the least operation information.

In one or more example embodiments, at least one defect point may exist in the fourth defect cluster C4. The system 200 may detect an initial defect point from among the defect points included in the fourth defect cluster C4. The initial defect point of the defect cluster C4 may include a defect point having the least operation information from among the defect points belonging to the fourth defect cluster C4. In the fourth defect cluster C4, the earliest photo process corresponding to the least operation information may include the third photo process P3. When there are a plurality of defect points having the least operation information, the initial defect point of the fourth defect cluster C4 may include a defect point having a greatest height from among the defect points having the least operation information.

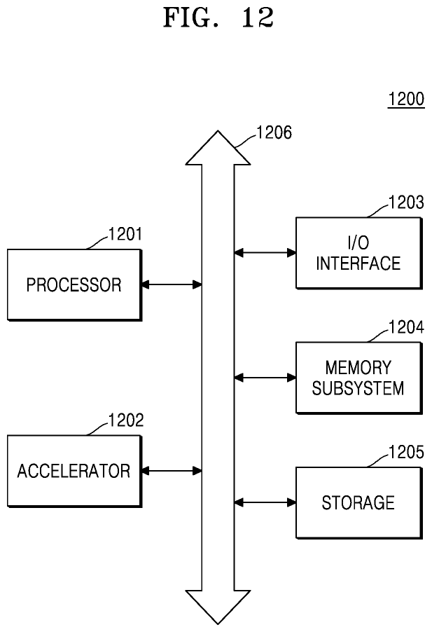

FIG. 12 is a block diagram of a system 1200 according to one or more example embodiments. In detail, the system 1200 shown in FIG. 12 may correspond to the system 200 according to one or more example embodiments shown in FIG. 1. FIG. 12 may be described with reference to one or more example embodiments shown in FIG. 1, and duplicate descriptions have been omitted.

As shown in FIG. 12, the system 1200 may include a processor 1201, an accelerator 1202, an input/output (I/O) interface 1203, a memory subsystem 1204, a storage 1205, and a bus 1206. The processor 1201, the accelerator 1202, the I/O interface 1203, the memory subsystem 1204, and the storage 1205 may communicate with one another through the bus 1206. In one or more example embodiments, the system 1200 may include a system-on-chip (SoC) in which components are implemented in one chip, and the storage 1205 may be outside the SoC. In one or more example embodiments, at least one of the components shown in FIG. 12 may be omitted from the system 1200.

The processor 1201 may control operations of the system 1200 on an uppermost layer, and may also control other components included in the system 1200.

In one or more example embodiments, the processor 1201 may include two or more processing cores. As described above with reference to the drawings, the processor 1201 may process various processes required for the operation of the system 1200 to detect the initial defect point on the wafer.

The accelerator 1202 may be designed to perform designated functions at a high rate. For example, the accelerator 1202 may provide data, which is generated by processing data received from the memory subsystem 1204, to the memory subsystem 1204.

The I/O interface 1203 may provide an interface configured to receive inputs from outside the system 1200 and provide outputs to outside the system 1200. For example, the system 1200 may receive the first wafer level map WLM1 to the m^{th} wafer level map WLMm from an external source through the I/O interface 1203. For example, the system 1200 may receive the p value for the Lₚ norm and the critical threshold value CT through the I/O interface 1203 from the external source.

The memory subsystem 1204 may be accessed by other components connected to the bus 1206. In one or more example embodiments, the memory subsystem 1204 may include a volatile memory such as DRAM or SRAM, and may include a nonvolatile memory such as flash memory and resistive random access memory (RRAM). Furthermore, in one or more example embodiments, the memory subsystem 1204 may provide an interface for the storage 1205. The storage 1205 may include a storage medium that does not lose data even when disconnected from power. For example, the storage 1205 may include a semiconductor memory device such as a nonvolatile memory, and may also include a storage medium such as magnetic card/disc or optical card/disc. In one or more example embodiments, the first wafer level map WLM1 to the m^{th} wafer level map WLMm corresponding to the target wafer may be stored in the memory subsystem 1204 or the storage 1205. In one or more example embodiments, the composite wafer map, the defect cluster set, and the initial defect point set corresponding to the target wafer may be stored in the memory subsystem 1204 or the storage 1205.

The bus 1206 may operate based on various bus protocols. The various bus protocols may include, but are not limited to, at least one of Advanced Microcontroller Bus Architecture (AMBA) protocol, Universal Serial Bus (USB) protocol, MuitlMedia Card (MMC) protocol, Peripheral Component Interconnection (PCI) protocol, PCI-Express (PCI-E) protocol, Advanced Technology Attachment (ATA) protocol, Serial-ATA protocol, Parallel-ATA protocol, Small Computer Small Interface (SCSI) protocol, Enhanced Small Disk Interface (ESDI) protocol, Integrated Drive Electronics (IDE) protocol, Mobile Industry Processor Interface (MIPI) protocol, and Universal Flash Storage (UFS) protocol.

While one or more example embodiments have been particularly shown and described above, it will be apparent to those skilled in the art that various changes in form and details may be made therein without departing from the spirit and scope of the following claims.

What is claimed is:

1. A method of detecting defects of a wafer, the method comprising:
generating a composite wafer map comprising defect points by combining a plurality of wafer level maps generated by measuring the wafer according to respective process operations;
sorting the defect points according to defect clusters based on positions of the defect points included in the composite wafer map; and
detecting an initial process operation in which a defect occurred, from among the respective process operations, based on operation information, for each of the defect clusters.

2. The method of claim 1, wherein the sorting of the defect points according to the defect clusters comprises:
setting a first defect point, which is selected from among the defect points included in the composite wafer map, as a reference defect point;
adding the reference defect point to a first defect cluster of the defect clusters;
searching for a defect point that is adjacent to the reference defect point, from among the defect points; and
adding the defect point that is adjacent to the reference defect point to the first defect cluster of the defect clusters.

3. The method of claim 2, wherein the searching for the defect point that is adjacent to the reference defect point comprises:
determining a distance between the reference defect point and each of the defect points included in the composite wafer map; and
extracting, from the defect points, a defect point that is located at a distance from the reference defect point that is less than or equal to a critical threshold value.

4. The method of claim 3, wherein the distance is determined using a Lₚ norm value regarding a position of the reference defect point and respective positions of the defect points.

5. The method of claim 3, further comprising:
updating the extracted defect point as a second reference defect point; and
searching for the defect point that is adjacent to the second reference defect point.

6. The method of claim 2, further comprising determining whether there is at least one unsorted defect point not belonging to any one of the defect clusters from among the defect points.

7. The method of claim 6, further comprising:
based on determining that there is at least one unsorted defect point, updating a second defect point selected from among the at least one unsorted defect point as a third reference defect point and adding the third reference defect point to a second defect cluster of the defect clusters; and
searching for a defect point of the defect points that is adjacent to the third reference defect point.

8. The method of claim 1, further comprising extracting a defect point of the defect points having a greatest height based on the detected initial process operation for each of the defect clusters.

9. An apparatus for detecting defects of a wafer, the apparatus comprising:
a memory storing a program; and
a processor configured to execute the program stored in the memory to:
generate a composite wafer map comprising defect points by combining a plurality of wafer level maps generated by measuring the wafer according to respective process operations;
sort the defect points according to defect clusters based on positions of the defect points included in the composite wafer map; and
detect an initial process operation, from among the respective process operations, in which a defect occurred, based on operation information, for each of the defect clusters.

10. The apparatus of claim 9, wherein the processor is further configured to:
set a first defect point, which is selected from among the defect points included in the composite wafer map, as a reference defect point;
add the reference defect point to a first defect cluster of the defect clusters;
search for a defect point of the defect points that is adjacent to the reference defect point; and
add the defect point that is adjacent to the reference defect point to the first defect cluster.

11. The apparatus of claim 10, wherein the processor is further configured to:
determine a distance between the reference defect point and each of the defect points included in the composite wafer map; and
extract, from the defect points, a defect point located at a distance from the reference defect point that is less than or equal to a critical threshold value.

12. The apparatus of claim 11, wherein the processor is further configured to:
update the extracted defect point as a second reference defect point; and
search for a defect point of the defect points that is adjacent to the second reference defect point.

13. The apparatus of claim 10, wherein the processor is further configured to:
determine whether there is at least one unsorted defect point not belonging to any one of the defect clusters from among the defect points,
based on determining that there is at least one unsorted defect point, update a second defect point selected from among the at least one unsorted defect point as a third reference defect point and add the third reference defect point to a second defect cluster of the defect clusters; and
search for a defect point of the defect points that is adjacent to the third reference defect point.

14. The apparatus of claim 9, wherein the processor is further configured to extract a defect point of the defect points having a greatest height, based on the detected initial process operation for each of the defect clusters.

15. A non-transitory computer-readable storage medium configured to store instructions that, when executed by a processor, cause the processor to perform operations comprising:
generating a composite wafer map comprising defect points by combining a plurality of wafer level maps generated by measuring a wafer according to respective process operations;
sorting the defect points according to defect clusters based on positions of the defect points included in the composite wafer map; and
detecting an initial process operation, from among the respective process operations, in which a defect occurred, based on operation information, for each of the defect clusters.

16. The non-transitory computer-readable storage medium of claim 15, wherein the sorting of the defect points according to the defect clusters comprises:
setting a first defect point, which is selected from among the defect points included in the composite wafer map, as a reference defect point;
adding the reference defect point to a first defect cluster of the first defect clusters;
searching for a defect point of the defect points that is adjacent to the reference defect point; and
adding the defect point that is adjacent to the reference defect point to the first defect cluster.

17. The non-transitory computer-readable storage medium of claim 16, wherein the searching for the defect point that is adjacent to the reference defect point comprises:
determining a distance between the reference defect point and each of the defect points; and
extracting, from the defect points, a defect point located at a distance from the reference defect point that is less than or equal to a critical threshold value.

18. The non-transitory computer-readable storage medium of claim 17, further comprising:
updating the extracted defect point as a second reference defect point; and
searching for a defect point of the defect points that is adjacent to the second reference defect point.

19. The non-transitory computer-readable storage medium of claim 17, further comprising:
based on determining there is at least one unsorted defect point not belonging to any one of the defect clusters from among the defect points included in the composite wafer map, updating a second defect point selected from among the at least one unsorted defect point as a third reference defect point and adding the third reference defect point to a second defect cluster of the defect clusters; and
searching for a defect point of the defect points that is adjacent to the third reference defect point.

20. The non-transitory computer-readable storage medium of claim 15, further comprising extracting a defect point of the defect points having a greatest height, using the detected initial process operation, according to each of the defect clusters.
